(19) United States
(12) Patent Application Publication
(10) Pub. No.: US 2025/0291000 A1
(43) Pub. Date: Sep. 18, 2025

(54) GROUNDING IMPEDANCE MEASUREMENT APPARATUS AND METHOD, AND INVERTER

(71) Applicant: HOYMILES POWER ELECTRONICS INC., Hangzhou (CN)

(72) Inventors: Keyan SHI, Hangzhou (CN); Hongbin YU, Hangzhou (CN); Yi ZHAO, Hangzhou (CN); Bo YANG, Hangzhou (CN)

(21) Appl. No.: 19/228,446

(22) Filed: Jun. 4, 2025

Related U.S. Application Data
(63) Continuation of application No. PCT/CN2023/125318, filed on Oct. 19, 2023.

(30) Foreign Application Priority Data
Dec. 12, 2022 (CN) 202211591079.0

(51) Int. Cl. G01R 31/52

(52) U.S. Cl. CPC G01R 31/52

(57) ABSTRACT

A grounding impedance measurement apparatus and method, and an inverter are provided. The measurement apparatus includes a signal source, a coupling impedance network, a voltage division network, a sampling module, and a controller, the coupling impedance network is connected to the signal source, and couples an excitation signal between a direct-current input terminal and an alternating-current output terminal of an inverter; the voltage division network performs voltage division on the voltage between the direct-current input terminal and the alternating-current output terminal to provide a divided voltage; the sampling module is connected to the voltage division network, samples the divided voltage, and acquires a sampled voltage; and the controller is connected to the signal source and the sampling module, respectively, and acquires a grounding impedance of the direct-current input terminal of the inverter.

### CROSS-REFERENCE TO RELATED APPLICATIONS

This application is a continuation of international patent application No. PCT/CN2023/125318, filed on Oct. 19, 2023, which itself claims priority to Chinese patent application No. 202211591079.0, filed on Dec. 12, 2022, and titled “GROUNDING IMPEDANCE MEASUREMENT APPARATUS AND METHOD, AND INVERTER”. The contents of the above identified applications are hereby incorporated herein in their entireties by reference.

### TECHNICAL FIELD

The present disclosure generally relates to the field of photovoltaic power generation technology, and in particular, to a grounding impedance measurement apparatus and method, and an inverter.

### BACKGROUND

In a photovoltaic grid-connected system, when a DC (direct current) resistance of an output terminal of a photovoltaic module to the ground is too small, short-circuit risks on a DC side and an AC (Alternating Current) side will result in system security risks. Therefore, it needs to perform grounding impedance detection on the DC side for the photovoltaic grid-connected system.

Currently, most inverters have a metal housing and the housing is grounded. In a used grounding impedance detection manner, a grounding potential point of the housing is used. In a detection method, a resistance with a fixed resistance value is connected between the grounding potential point of the housing and a positive electrode of the photovoltaic assembly, and between the grounding potential point of the housing and a negative electrode of the photovoltaic assembly, respectively, by switching of a relay or a semiconductor switch. Meanwhile, voltage values at the grounding potential point of the housing are collected successively, and a grounding impedance value between two terminals of the photovoltaic module and the ground are calculated according to the voltage values.

Due to these methods use the grounding potential point of the housing, these methods are not applicable to inverters that are non-metallic and have no grounding wire connection.

### SUMMARY

According to various embodiments of the present disclosure, a grounding impedance measurement apparatus and method, and an inverter are provided.

In a first aspect, a grounding impedance measurement apparatus is provided in the present disclosure, including a signal source, a coupling impedance network, a voltage division network, a sampling module, and a controller. The signal source is configured to provide an excitation signal. The coupling impedance network is connected to the signal source, and configured to couple the excitation signal between a direct-current input terminal and an alternating-current output terminal of an inverter, and the alternating-current output terminal of the inverter is connected to a power grid. The voltage division network is configured to perform voltage division on a voltage between the direct-current input terminal and the alternating-current output terminal to provide a divided voltage. The sampling module is connected to the voltage division network, and configured to sample the divided voltage and acquire a sampled voltage. The controller is connected to the signal source and the sampling module, respectively, and configured to control the signal source to provide at least one excitation signal and acquire a grounding impedance of the direct-current input terminal of the inverter according to the at least one excitation signal and the sampled voltage corresponding to the at least one excitation signal.

In some embodiments, the controller is further configured to control the signal source to provide a first excitation signal and a second excitation signal, respectively, the sampling module is further configured to acquire a first sampled voltage corresponding to the first excitation signal and a second sampled voltage corresponding to the second excitation signal, and the controller is further configured to acquire the grounding impedance of the direct-current input terminal of the inverter according to a difference between the first excitation signal and the second excitation signal and a difference between the first sampled voltage and the second sampled voltage.

In some embodiments, an output terminal of the signal source is connected to a port of the direct-current input terminal and the other output terminal of the signal source is connected to a port of the alternating-current output terminal via the coupling impedance network.

In some embodiments, the signal source includes a direct-current voltage conversion circuit or a rectifier circuit.

In some embodiments, the signal source includes a switch circuit, which includes at least one switch, and different excitation signals are output by controlling an on-state of the at least one switch.

In some embodiments, the inverter includes a full-bridge circuit or a half-bridge circuit, which is connected to the direct-current input terminal, the signal source is a part of the full-bridge circuit or a part of the half-bridge circuit, and the excitation signal includes a direct-current input voltage of the direct-current input terminal or 0.

In some embodiments, the voltage division network is connected between a port of the direct-current input terminal of the inverter and a port of the alternating-current output terminal of the inverter.

In some embodiments, the voltage division network is connected to the coupling impedance network in series.

In some embodiments, the sampling module includes a first sampling unit, which is connected to the voltage division network and configured to acquire the sampled voltage.

In some embodiments, the first sampling unit includes a filtering circuit and a sampling circuit, and the filtering circuit is connected to the voltage division network and the sampling circuit, respectively, and configured to filter a voltage component in the sampled voltage other than a voltage component with a frequency of the excitation signal.

In some embodiments, the controller includes a filtering unit configured to filter a voltage component in the sampled voltage other than a voltage component with a frequency of the excitation signal.

In some embodiments, the sampling module further includes a second sampling unit connected to the direct-current input terminal of the inverter and configured to acquire a direct-current input voltage and provide the direct-current input voltage to the controller, and the controller is configured to control the signal source to provide at least two different excitation signals, and acquire the grounding impedance of the direct-current input terminal of the inverter according to the at least two different excitation signals and sampled voltages and direct-current input voltages corresponding to the at least two different excitation signals.

In some embodiments, the excitation signal includes a direct-current signal, an alternating-current signal, or a superposed signal of a direct-current signal and an alternating-current signal.

In some embodiments, the controller is configured to compare the grounding impedance with a preset threshold to determine whether the grounding impedance is abnormal.

In a second aspect, a grounding impedance measurement method is provided in the present disclosure, which is configured to measure a grounding impedance of a direct-current input terminal of an inverter. The method includes: coupling at least one excitation signal between the direct-current input terminal and an alternating-current output terminal of the inverter; performing voltage division on a voltage between the direct-current input terminal and the alternating-current output terminal of the inverter to obtain a sampled voltage; and acquiring a grounding impedance of the direct-current input terminal of the inverter according to the at least one excitation signal and the sampled voltage corresponding to the at least one excitation signal.

In some embodiments, the method further includes: coupling a first excitation signal and a second excitation signal between the direct-current input terminal and the alternating-current output terminal of the inverter, respectively; and acquiring a first sampled voltage corresponding to the first excitation signal and a second sampled voltage corresponding to the second excitation signal, respectively, and acquiring the grounding impedance of the direct-current input terminal of the inverter according to a difference between the first excitation signal and the second excitation signal and a difference between the first sampled voltage and the second sampled voltage.

In some embodiments, the method further includes: coupling at least two different excitation signals between the direct-current input terminal and the alternating-current output terminal of the inverter, respectively; and acquiring direct-current input voltages of the direct-current input terminal of the inverter and sampled voltages corresponding to the at least two different excitation signals, and acquiring the grounding impedance of the direct-current input terminal of the inverter according to the at least two different excitation signals and the direct-current input voltages and the sampled voltages corresponding to the at least two different excitation signals.

In some embodiments, the method further includes: comparing the grounding impedance with a preset threshold to determine whether the grounding impedance is abnormal.

In a third aspect, an inverter is provided in the present disclosure, including the grounding impedance measurement apparatus in the first aspect and a DC/AC converter. The DC/AC converter is connected between the direct-current input terminal and the alternating-current output terminal of the inverter and configured to convert a direct current to an alternating current.

Details of one or more embodiments of the present disclosure are proposed in the following accompanying drawings and descriptions, so that other features, objects, and advantages of the present disclosure are more easily understood.

### BRIEF DESCRIPTION OF THE DRAWINGS

In order to more clearly describe technical solutions in the embodiments or the related art, the following briefly describes the accompanying drawings required for describing the embodiments or the conventional technologies. Apparently, the accompanying drawings in the following description show merely the embodiments of the present disclosure, and one skilled in the art may still derive other drawings from the disclosed accompanying drawings without creative efforts.

FIG. 1 is a block diagram of a power generation system in some embodiments.

FIG. 2 is a schematic diagram of a grounding impedance measurement apparatus in some embodiments.

FIG. 3 is a direct-current equivalent circuit model of FIG. 2.

FIG. 4 is an alternating-current equivalent circuit model of FIG. 2.

FIG. 5 is a schematic diagram of a grounding impedance measurement apparatus in some embodiments.

FIG. 6 is a schematic diagram of a grounding impedance measurement apparatus in some embodiments.

FIG. 7 is a direct-current equivalent circuit model of FIG. 6.

FIG. 8 is a schematic diagram of a signal source in some embodiments.

FIG. 9 is a schematic diagram of a signal source in some embodiments.

FIG. 10 is a schematic diagram of a signal source in some embodiments.

FIG. 11 is a schematic diagram of a signal source in some embodiments.

FIG. 12 is a schematic diagram of a first sampling unit in some embodiments.

FIG. 13 is a flowchart of a grounding impedance measurement method in some embodiments.

In the figures, 100 represents an inverter, 110 represents a grounding impedance measurement apparatus, 111 represents a coupling impedance network, 112 represents a voltage division network, 113 represents a sampling module, 113a represents a first sampling unit, 113b represents a second sampling unit, 114 represents a controller, 115 represents a filtering circuit, 116 represents a sampling circuit, 120 represents a DC/AC converter, V_{c} represents a signal source, Vₚᵥ represents a direct-current input voltage, R₁ represents a first resistor, R₂ represents a second resistor, R₃ represents a third resistor, R₄ represents a fourth resistor, Rₓ represents a fifth resistor, R_{E1} represents a grounding impedance of a negative port of a direct-current input terminal, R_{E2} represents a grounding impedance of a positive port of a direct-current input terminal, PE represents a grounding point, 200 represents a direct current source, 300 represents a power grid.

### DETAILED DESCRIPTION OF THE EMBODIMENT

The following clearly and completely describes the technical solutions in the embodiments of the present disclosure with reference to the accompanying drawings in the embodiments of the present disclosure. Apparently, the described embodiments are merely some rather than all of the embodiments of the present disclosure. Based on the embodiments of the present disclosure, all other embodiments obtained by one skilled in the art without creative efforts fall within the protection scope of the present disclosure.

When a component is considered to be “connected” to another component, it may be directly connected to another component or a centered component may be present. When one component is considered to be connected to another component “in series” or “in parallel”, it may be either directly connected to another component in series or in parallel or may be accompanied by a centered component.

Unless otherwise defined, all technical and scientific terms used in this specification have the same meaning as is generally understood by one skilled in the art that belong to the present disclosure. The terms used in the specification of the present disclosure are merely intended to describe specific embodiments, and are not intended to limit the present disclosure.

A grounding impedance measurement apparatus provided in the present disclosure may be applied to a power generation system.

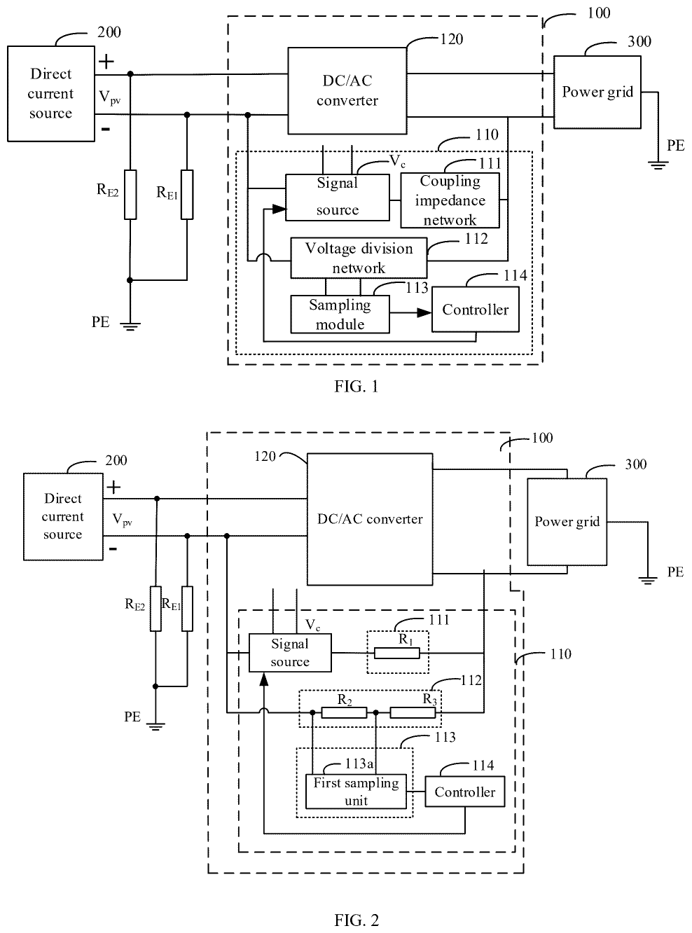

FIG. 1 is a block diagram of a power generation system provided in the present disclosure. Referring to FIG. 1, the power generation system may include an inverter 100 and a direct current source 200 connected to a direct-current input terminal of the inverter 100. The inverter 100 is configured to convert a direct current provided by the direct current source 200 into an alternating current, and further provide the alternating current to a power grid 300.

In some embodiments, the direct current source 200 may include a photovoltaic module.

In some embodiments, the direct current source 200 may include a photovoltaic string or an array formed by a plurality of photovoltaic modules connected in series and parallel, or may include a battery or another type of renewable energy source.

The inverter 100 may include an isolated or non-isolated inverter, and may include a single-stage inverter or a multi-stage inverter.

In some embodiments, a chassis of the inverter 100 may not be grounded.

The power grid 300 may be a single-phase power grid, a three-phase power grid, or a split-phase power grid.

A remote end of the power grid 300 may be grounded by a zero line. A grounding point may be located at a positive end of the power grid 300, or a negative end of the power grid 300. When the power grid is the split-phase grid, the grounding point may be located at a midpoint of the power grid 300. A location of the grounding point does not affect the grounding impedance measurement in the embodiment of the present disclosure.

Referring to FIG. 1, the inverter 100 includes a DC/AC converter 120 and a grounding impedance measurement apparatus 110, and the grounding impedance measurement apparatus 110 includes a signal source V_{c}, a coupling impedance network 111, a voltage division network 112, a sampling module 113, and a controller 114.

The signal source V_{c} is connected between a direct-current input terminal and an alternating-current output terminal of the inverter 100 and configured to provide an excitation signal.

The coupling impedance network 111 is connected to the signal source V_{c}, and configured to couple the excitation signal between the direct-current input terminal and the alternating-current output terminal of the inverter 100. The alternating-current output terminal of the inverter 100 is connected to the power grid 300.

The voltage division network 112 is configured to perform voltage division on a voltage between the direct-current input terminal and the alternating-current output terminal to provide a divided voltage.

The sampling module 113 is connected to the voltage division network 112, and configured to acquire a sampled voltage of the voltage division network 112.

The controller 114 is connected to the signal source V_{c} and the sampling module 113, respectively. The controller 114 is configured to control the signal source V_{c} to provide at least one excitation signal and acquire a grounding impedance of the direct-current input terminal of the inverter 100 according to the at least one excitation signal and the sampled voltage corresponding to the at least one excitation signal.

In the present embodiment, the signal source V_{c} and the coupling impedance network 111 are disposed between the direct-current input terminal and the alternating-current output terminal of the inverter 100, to construct a high-resistance circuit. The excitation signal is introduced into the high-resistance circuit, and the grounding impedance of the direct-current input terminal of the inverter 100 is acquired according to the excitation signal and the sampling voltage corresponding to the excitation signal.

It should be noted that the grounding impedance of the direct-current input terminal of the inverter 100 is the same as that of the direct current source 200 to the ground.

The signal source V_{c} may collect power from the direct current source 200, or from other power supply of the power generation system. An input of the signal source V_{c} may be a direct-current power supply, or may be an alternating-current power supply.

In some embodiments, a first output terminal of the signal source V_{c} may be connected to a negative port of a direct-current input terminal of the DC/AC converter 120 (i.e., a negative port of the direct-current input terminal of the inverter 100), and a second output terminal of the signal source V_{c} may be connected to a port of the alternating-current output terminal of the DC/AC converter 120.

In some embodiments, the first output terminal of the signal source V_{c} may be connected to a positive port of the direct-current input terminal of the DC/AC converter 120 (i.e., a positive port of the direct-current input terminal of the inverter 100). By control of the controller 114, the second output terminal of the signal source V_{c} may generate at least one controlled excitation signal relative to the first output terminal of the signal source V_{c}.

In some embodiments, the grounding impedance measurement apparatus 110 is configured in an inverter 100 with a non-metal housing and no grounding line. In a case that the inverter 100 has no grounding line, the grounding impedance of the direct current source 200 may be measured.

FIG. 2 is a schematic diagram of a grounding impedance measurement apparatus in an embodiment. Referring to FIG. 2, R_{E1} represents a grounding impedance of a negative port of a direct-current output terminal of the direct current source 200 (i.e., the negative port of the direct-current input terminal of the inverter 100), and R_{E2} represents a grounding impedance of a positive port of a direct-current output terminal of the direct current source 200 (i.e., the positive port of the direct-current input terminal of the inverter 100). The signal source V_{c} is configured to provide the excitation signal. The coupling impedance network 111 may include a first resistor R₁. The first resistor R₁ may be connected to an output terminal of the signal source V_{c} in series, and connected between a port of the direct-current input terminal of the DC/AC converter 120 and a port of the alternating-current output terminal of the DC/AC converter 120. The first resistor R₁ is configured to limit an impedance value between a DC side and an AC side of the inverter 100 when the inverter 100 is in operation normally.

Specifically, the first output terminal of the signal source V_{c} may be connected to the negative port of the direct-current input terminal of the DC/AC converter 120, the second output terminal of the signal source V_{c} may be connected to a first terminal of the first resistor R₁, and a second terminal of the first resistor R₁ may be connected to a first port of the alternating-current output terminal of the DC/AC converter 120.

In some embodiments, the first output terminal of the signal source V_{c} may be connected to the positive port of the direct-current input terminal of the DC/AC converter 120, the second output terminal of the signal source V_{c} may be connected to the first terminal of the first resistor R₁, and the second terminal of the first resistor R₁ may be connected to a second port of the alternating-current output terminal of the DC/AC converter 120.

In some embodiments, the voltage division network 112 may include a second resistor R₂ and a third resistor R₃, and the second resistor R₂ and the third resistor R₃ may be connected between the negative port of the direct-current input terminal of the DC/AC converter 120 and the first port of the alternating-current output terminal of the DC/AC converter 120.

In another embodiment, the second resistor R₂ and the third resistor R₃ may be connected between the positive port of the direct-current input terminal of the DC/AC converter 120 and the second port of the alternating-current output terminal of the DC/AC converter 120.

The sampling module 113 may include a first sampling unit 113a, which is configured to sample a voltage between two terminals of the second resistor R₂ to obtain a sampled voltage and provide the sampled voltage to the controller 114.

The controller 114 may control the signal source V_{c} to provide a first excitation signal and a second excitation signal, respectively, the first sampling unit 113a may acquire a first sampled voltage corresponding to the first excitation signal and a second sampled voltage corresponding to the second excitation signal, respectively, and the controller 114 may acquire the grounding impedance of the direct-current input terminal of the inverter 100 according to a difference between the first excitation signal and the second excitation signal and a difference between the first sampled voltage and the second sampled voltage.

In some embodiments, a resistance value of the first resistor R₁ may be generally in a range from several MΩ to dozens MΩ.

In some embodiments, a resistance value of the third resistor R₃ may be generally in the same level as that of the first resistor R₁, and the resistance value may be in a range from several MΩ to dozens MΩ, while a resistance value of the second resistor R₂ configured for voltage sampling may be generally far less than that of the third resistor R₃.

Specifically, the signal source V_{c} may output at least one excitation signal relative to the negative port of the direct-current input terminal of the DC/AC converter 120 by control of the controller 114, the corresponding sampling module 113 may sample and acquire at least one sampled voltage, and the controller 114 may obtain resistance values of the grounding impedance R_{E1} and the grounding impedance R_{E2} or a parallel resistance value of the grounding impedance R_{E1} and the grounding impedance R_{E2} according to the at least one excitation signal and the at least one sampled voltage corresponding to the at least one excitation signal, i.e., the grounding impedance of the direct-current input terminal of the inverter 100.

In some embodiments, the controller 114 may obtain the parallel resistance value of the grounding impedance R_{E1} and the grounding impedance R_{E2} according to at least two different excitation signals and sampled voltages under different disturbances.

The grounding impedance of the direct-current input terminal of the inverter 100 may include a grounding impedance of the positive port of the direct-current input terminal of the inverter 100 and a grounding impedance of the negative port of the direct-current input terminal of the inverter 100, or a parallel value of the grounding impedance of the positive port of the direct-current input terminal of the inverter 100 and the grounding impedance of the negative port of the direct-current input terminal of the inverter 100.

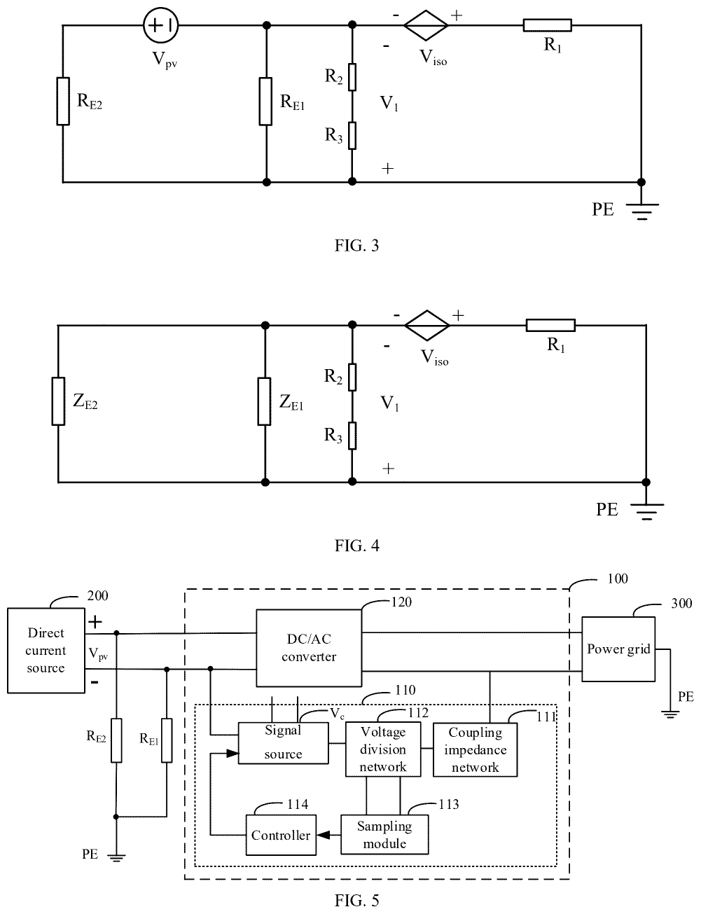

Referring to FIG. 2, the positive port of the direct-current output terminal of the direct current source 200 connected to the DC side of the inverter 100 may be connected to the ground by the grounding impedance R_{E2}, the negative port of the direct-current output terminal of the direct current source 200 connected to the DC side of the inverter 100 may be connected to the ground by the grounding impedance R_{E1}, and the AC side of the DC/AC converter 120 may connected to the ground by a zero line. Therefore, the first resistor R₁ and the signal source V_{c} may be connected between the direct-current input terminal and the alternating-current output terminal of the DC/AC converter 120 to form a closed circuit. If only a DC component in the closed circuit is considered, the AC side of the inverter 100 may be equivalent to direct grounding regardless of a grounding form of the power grid connected to the AC side of the inverter 100. When only the DC component in the system is considered, the above grounding impedance measurement apparatus 110 may be simplified as a DC equivalent circuit model shown in FIG. 3. Vᵢₛₒ may be the excitation signal output by the signal source V_{c}, the excitation signal Vᵢₛₒ may include a DC voltage, Vₚᵥ may be a DC output voltage of the direct current source 200, i.e., a DC input voltage of the direct-current input terminal of the inverter 100, and Vₚᵥ may be a stable value in a measurement process. A voltage V₁ between two terminals of the second resistor R₂ and the third resistor R₃ shown in FIG. 3 may be represented as:

$${V}_{1} = \frac{{R}_{E 1} / / ( {R}_{2} + {R}_{3} ) / / {R}_{1}}{{R}_{E 2} + {R}_{E 1} / / ( {R}_{2} + {R}_{3} ) / / {R}_{1}} {V}_{p v} + \frac{{R}_{E 1} / / ( {R}_{2} + {R}_{3} ) / / {R}_{E 2}}{{R}_{1} + {R}_{E 1} / / ( {R}_{2} + {R}_{3} ) / / {R}_{E 2}} {V}_{i s o} \qquad ( 1 )$$

The sampled voltage Vₛₐₘ obtained by the first sampling unit 113a sampling a division voltage of the second resistor R₂ may satisfy the following relationship:

$${V}_{s a m} = {V}_{1} \frac{{R}_{2}}{{R}_{2} + {R}_{3}}$$

The grounding impedance measurement in the present embodiment may include the following step 1 to step 5.

Step 1 may include the controller 114 controlling the signal source V_{c} to output an excitation signal Vᵢₛₒ₁.

Step 2 may include after the excitation signal Vᵢₛₒ₁ output by the signal source V_{c} is stabilized, the first sampling unit 113a sampling the division voltage between two terminals of the second resistor R₂ to obtain a sampled voltage Vₛₐₘ₁.

Step 3 may include the controller 114 controlling the signal source V_{c} to output an excitation signal Vᵢₛₒ₂.

Step 4 may include after the excitation signal Vᵢₛₒ₂ output by the signal source V_{c} is stabilized, the first sampling unit 113a sampling the division voltage between two terminals of the second resistor R₂ to obtain a sampled voltage Vₛₐₘ₂.

Step 5 may include acquiring the parallel resistance value of the grounding impedance R_{E1} and the grounding impedance R_{E2} according to the excitation signal Vᵢₛₒ₁, the excitation signal Vᵢₛₒ₂, the sampled voltage Vₛₐₘ₁, and the sampled voltage Vₛₐₘ₂.

An acquiring method of resistance values of the grounding impedance R_{E1} and the grounding impedance R_{E2} at step S5 may be as follows: according to the two excitation signals provided by the signal source V_{c} and the two sampled voltages, two equations may be listed according to the formula (1):

$$\{ \begin{matrix}\begin{matrix}{V}_{sam 1} \frac{{R}_{2} + {R}_{3}}{{R}_{2}} = \frac{{R}_{E 1} / / ( {R}_{2} + {R}_{3} ) / / {R}_{1}}{{R}_{E 2} + {R}_{E 1} / / ( {R}_{2} + {R}_{3} ) / / {R}_{1}} {V}_{p v} + \\ \frac{{R}_{E 1} / / ( {R}_{2} + {R}_{3} ) / / {R}_{E 2}}{{R}_{1} + {R}_{E 1} / / ( {R}_{2} + {R}_{3} ) / / {R}_{E 2}} {V}_{iso 1}\end{matrix} \\ \begin{matrix}{V}_{sam 2} \frac{{R}_{2} + {R}_{3}}{{R}_{2}} = \frac{{R}_{E 1} / / ( {R}_{2} + {R}_{3} ) / / {R}_{1}}{{R}_{E 2} + {R}_{E 1} / / ( {R}_{2} + {R}_{3} ) / / {R}_{1}} {V}_{p v} + \\ \frac{{R}_{E 1} / / ( {R}_{2} + {R}_{3} ) / / {R}_{E 2}}{{R}_{1} + {R}_{E 1} / / ( {R}_{2} + {R}_{3} ) / / {R}_{E 2}} {V}_{iso 2}\end{matrix}\end{matrix}$$

according to the above equations, the parallel resistance values of the ground impedance R_{E1} and R_{E2} may be obtained. The parallel resistance values of the ground impedance R_{E1} and R_{E2} may be as follows:

$${R}_{E 1} / / {R}_{E 2} = \frac{( {V}_{sam 2} - {V}_{sam 1} ) {R}_{1} ( {R}_{2} + {R}_{3} )}{( {V}_{sam 1} - {V}_{sam 2} ) ( {R}_{1} + {R}_{2} + {R}_{3} ) - {R}_{2} ( {V}_{iso 1} - {V}_{iso 2} )} \qquad ( 2 )$$

In some embodiments, the controller 114 may control the signal source V_{c} to output at least two different excitation signals, sample the division voltage between the two terminals of the second resistor R2 to obtain sampled voltages Vₛₐₘᵢ, acquire the grounding impedance according any two different excitation signals and the sampled voltages Vₛₐₘᵢ corresponding to the two different excitation signals, and further average a plurality of obtained grounding impedances, thereby further improving accuracy of the measured grounding impedance.

In some embodiments, the sample module 113 may further include a second sampling unit 113b, which is connected to the direct-current input terminal of the inverter 100 and configured to acquire a direct-current input voltage and provide the direct-current input voltage to the controller 114, and the controller 114 is configured to control the signal source Vc to provide at least two different excitation signals and acquire the grounding impedance of the direct-current input terminal of the inverter 100 according to the at least two different excitation signals and the sampled voltages corresponding to the at least two different excitation signals. The second sampling unit 113b may be similar to the first sampling unit 113a.

In some embodiment, when the direct-current input voltage is unstable, the direct-current input voltage may be sampled under a corresponding excitation signal, and the parallel value of the grounding impedance R_{E1} and the grounding impedance R_{E2} of the direct-current input terminal of the inverter 100 may be acquired according to the at least two different excitation signals, the sampled voltages corresponding to the at least two different excitation signals, and the direct-current input voltage.

A formula for acquiring the parallel value of the grounding impedance R_{E1} and the grounding impedance R_{E2} may be as follows:

$${R}_{E 1} / / {R}_{E 2} = \frac{( {V}_{sam 2} {V}_{pv 1} - {V}_{sam 1} {V}_{pv 2} ) {R}_{1} ( {R}_{2} + {R}_{3} )}{( {V}_{sam 1} {V}_{pv 2} - {V}_{sam 2} {V}_{pv 1} ) ( {R}_{1} + {R}_{2} + {R}_{3} ) - {R}_{2} ( {V}_{pv 2} {V}_{iso 1} - {V}_{pv 1} {V}_{iso 2} )}$$

Furthermore, it may be determined, according to the resistance value of the grounding impedance, whether a grounding fault occurs in the direct current source 200.

Furthermore, the controller 114 may compare the parallel value of the grounding impedance R_{E1} and the grounding impedance R_{E2} with a preset threshold to determine whether the grounding impedance is abnormal and whether a grounding fault of the direct-current input terminal occurs. For example, when the parallel value is less than the preset threshold, it may be determined that the direct-current input terminal of the inverter has the grounding fault.

In some embodiments, the controller 114 may compare the grounding impedance R_{E2} and the grounding impedance R_{E1} with a corresponding preset threshold, respectively, determine whether the grounding impedance R_{E1} and the grounding impedance R_{E2} are abnormal, and determine whether a grounding fault occurs in the direct-current input terminal of the inverter.

In some embodiments, the excitation signal output by the signal source V_{c} may include an alternating-current voltage V_{isoac} with a fixed frequency, and the fixed frequency may be different from a power grid frequency. When only the alternating-current voltage with the fixed frequency is considered, the grounding impedance measurement apparatus 110 may be simplified as an alternating-current equivalent circuit model shown in FIG. 4. A parallel value of a grounding impedance Z_{E1} and a grounding impedance Z_{E2} may be calculated in the same manner, and it may be determined, by a resistance value, whether the ground impedance of the direct current source 200 is abnormal. The parallel value of the grounding impedance Z_{E1} and the grounding impedance Z_{E2} may be obtained by the following formulas.

$${V}_{s a m} \frac{{R}_{2} + {R}_{3}}{{R}_{2}} = {V}_{isoac} \frac{{Z}_{E 1} / / {Z}_{E 2} / / ( {R}_{2} + {R}_{3} )}{{R}_{1} + {Z}_{E 1} / / {Z}_{E 2} / / ( {R}_{2} + {R}_{3} )}$$

$${Z}_{E 1} / / {Z}_{E 2} = \frac{{V}_{s a m} {R}_{1} ( {R}_{2} + {R}_{3} )}{{V}_{isoac} {R}_{2} - {V}_{s a m} ( {R}_{1} + {R}_{2} + {R}_{3} )}$$

In the formulas, both V_{isoac} and Vₛₐₘ may be AC voltage amplitudes corresponding to the frequency of the excitation signal.

Furthermore, the grounding impedance Z_{E1} and the grounding impedance Z_{E2} may be obtained by different excitation signals V_{isoac} provided by the signal source V_{c}.

In some embodiments, the excitation signal output by the signal source V_{c} may include a superposed signal of a direct-current signal and an alternating-current signal with a fixed frequency. Referring to a principle of the above embodiments, the grounding impedance of the direct-current input terminal of the inverter 100 may be obtained. Details may not be described herein again.

In some embodiments, referring to FIG. 5, the voltage division network 112 may be connected to the output terminal of the signal source V_{c} and the coupling impedance network 111 in series, respectively.

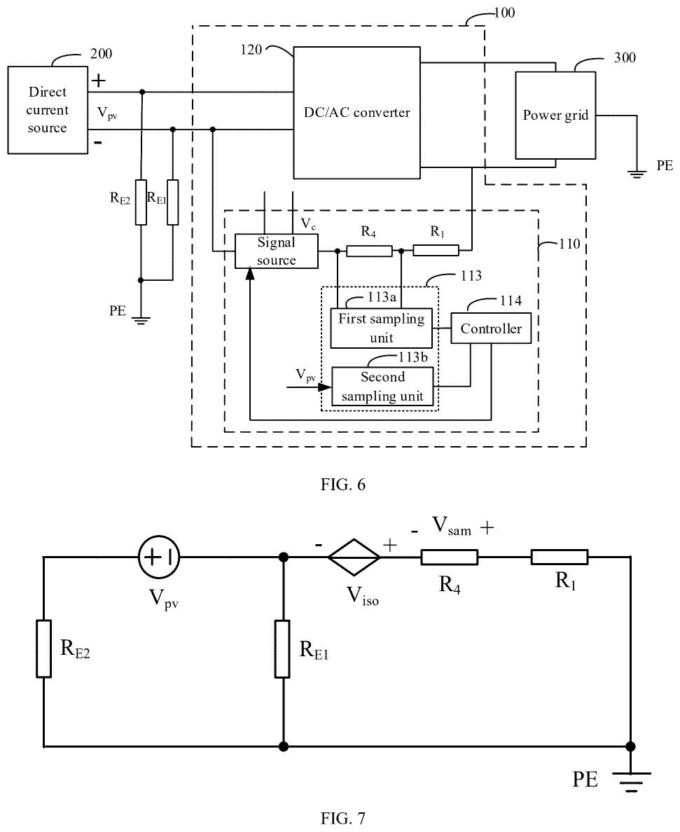

In some embodiments, referring to FIG. 6, the voltage division network 112 may include a fourth resistor R₄, the coupling impedance network 111 may include a first resistor R₁, the fourth resistor R₄ may be connected to the coupling impedance network 111 in series, and two terminals of the fourth resistor R₄ may provide a division voltage. The second output terminal of the signal source V_{c} may be connected to the first terminal of the first resistor R₁ by the fourth resistor R₄, and a second terminal of the first resistor R₁ may be connected to the second port of the alternating-current output terminal.

In some embodiments, the second output terminal of the signal source V_{c} may be connected to a first terminal of the fourth resistor R₄ by the first resistor R₁, and a second terminal of the fourth resistor R₄ may be connected to the second port of the alternating-current output terminal.

The first sampling unit 113a in the sampling module 113 is configured to sample a voltage between two terminals of the fourth resistor R₄ to obtain a sampled voltage and provide the sampled voltage to the controller 114, the second sampling unit 113b is configured to sample a voltage of the direct-current input terminal of the inverter 100 to obtain the direct-current input voltage and provide the sampled voltage to the controller 114.

Furthermore, a resistance value of the fourth resistor R₄ may be far less than that of the first resistor R₁.

Specifically, the direct-current equivalent circuit model of the grounding impedance measurement apparatus 110 may refer to FIG. 7. Steps of grounding impedance measurement in the present embodiment may be the same as that in the above embodiments, and the following equation may be obtained by the same derivation:

$$\{ \begin{matrix}\begin{matrix}{V}_{sam 1} {V}_{pv 2} \frac{{R}_{1} + {R}_{4}}{{R}_{4}} = \frac{{R}_{E 1} / / ( {R}_{1} + {R}_{4} )}{{R}_{E 2} + {R}_{E 1} / / ( {R}_{1} + {R}_{4} )} {V}_{pv 1} \\ {V}_{pv 2} - \frac{{R}_{1} + {R}_{4}}{{R}_{1} + {R}_{4} + {R}_{E 1} / / {R}_{E 2}} {V}_{iso 1} {V}_{pv 2}\end{matrix} \\ \begin{matrix}{V}_{sam 2} {V}_{pv 1} \frac{{R}_{1} + {R}_{4}}{{R}_{4}} = \frac{{R}_{E 1} / / ( {R}_{1} + {R}_{4} )}{{R}_{E 2} + {R}_{E 1} / / ( {R}_{1} + {R}_{4} )} {V}_{pv 2} \\ {V}_{pv 1} - \frac{{R}_{1} + {R}_{4}}{{R}_{1} + {R}_{4} + {R}_{E 1} / / {R}_{E 2}} {V}_{iso 2} {V}_{pv 1}\end{matrix}\end{matrix}$$

Similarly, the parallel value of the grounding impedance R_{E1} and the grounding impedance R_{E2} may be obtained according to the above equation, and it may be determined, according to the parallel value, whether the ground impedance of the direct current source 200 is abnormal.

A structure and a connection manner of the voltage division network 112 may not be limited to the above specific embodiments, and may include other types of circuit structure, as long as the grounding impedance measurement can be performed with reference to the signal source V_{c}.

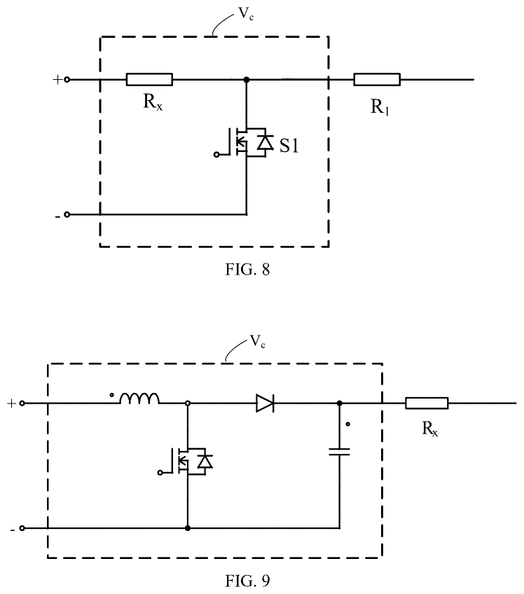

FIG. 8 is a schematic diagram of a circuit structure of the signal source V_{c} in an embodiment of the present disclosure. Referring to FIG. 8, an input terminal of the signal source V_{c} may be connected to, for example, the direct-current input terminal of the inverter 100. The signal source V_{c} may include a switch circuit, including a switch transistor S₁ and a fifth resistor Rₓ. The switch transistor S₁ and the fifth resistor Rₓ may be connected in series to the direct-current input terminal of the inverter 100. A connecting point of the switch transistor S₁ and the fifth resistor Rₓ may be connected to the first terminal of the first resistor R₁. The excitation signal output by the signal source V_{c} may be switched between 0 and Vₚᵥ by controlling on/off state of the switch transistor S₁. Specifically, when the switch transistor S₁ is in an on state, the output excitation signal may be 0 V. When the switch transistor S₁ is in an off state, since a resistance value of the fifth resistor Rₓ is far less than that of the first resistor R₁, the output excitation signal may be Vₚᵥ. The circuit structure may be simple and costs may be low.

To improve the difference between different excitation signals, FIG. 9 shows a schematic diagram of a circuit structure of the signal source V_{c} in an embodiment of the present disclosure. Referring to FIG. 9, the signal source V_{c} may be a boost converter, and the input terminal of the signal source V_{c} may be connected to, for example, the direct-current input terminal of the inverter 100. The excitation signal may be generated according to the direct-current input voltage Vₚᵥ. The controller 114 may output multiple different excitation signals by controlling a duty ratio of the switch transistor in the signal source V_{c}, and a range of the output excitation signal may be flexibly adjusted.

In some embodiments, the signal source V may include the boost converter and the switch circuit connected in series.

In some embodiments, the signal source V_{c} may include other forms of DC voltage conversion circuit, such as a flyback topology.

In some embodiments, the signal source V_{c} may include a rectifier circuit. In this case, the input terminal of the signal source V_{c} may receive alternating current, for example, a power supply from the power grid.

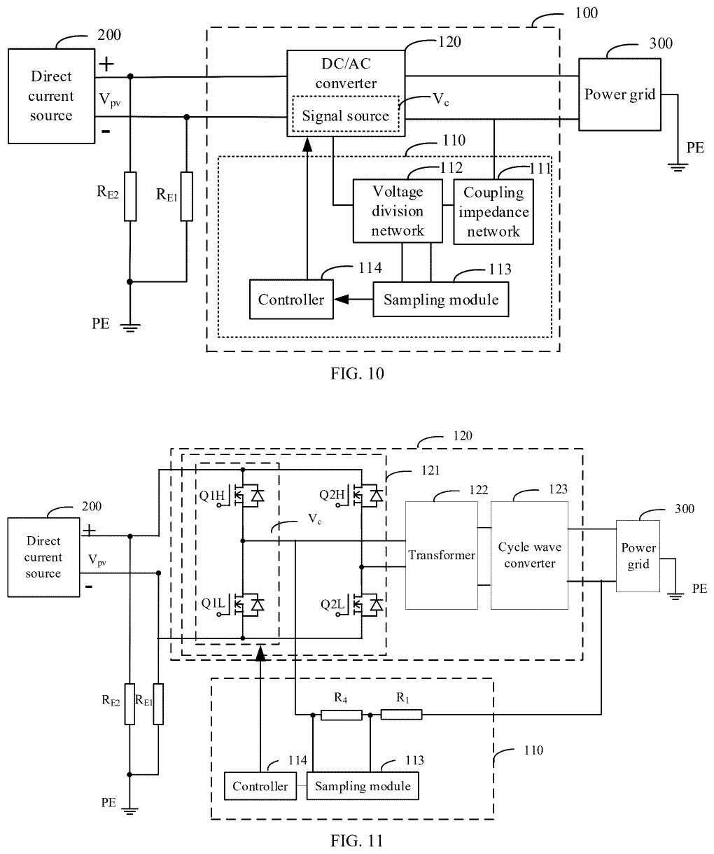

In some embodiments, the signal source V_{c} may be a part of the DC/AC converter 120. Referring to FIG. 10 and FIG. 11, the DC/AC converter 120 may include an inverting unit 121, a transformer 122, and a cycle wave converter 123. The inverting unit 121 is configured to perform inversion, the transformer 122 may be connected to the inverting unit 121 and configured to perform boost and electrical isolation, and the cycle wave converter 123 may be connected to the transformer 122 and configured to perform AC-to-AC conversion.

Specifically, the inverting unit 121 may include a full-bridge circuit, including a switch transistor Q1H and a switch transistor Q1L connected in series, and a switch transistor Q2H and a switch transistor Q2L connected in series. The switch transistor Q1H and the switch transistor Q1L may constitute the signal source V_{c}, a connecting midpoint of the switch transistor Q1H and the switch transistor Q1L may provide the excitation signal, and the excitation signal may include the direct-current input voltage or 0.

In some embodiments, the switch transistor Q2H and the switch transistor Q2L may constitute the signal source V_{c}, a connecting midpoint of the switch transistor Q2H and the switch transistor Q2L may provide the excitation signal, and the excitation signal may include the direct-current input voltage or 0.

In some embodiments, the inverting unit 121 may include a half-bridge circuit. In this case, the half-bridge circuit may be the signal source V_{c}.

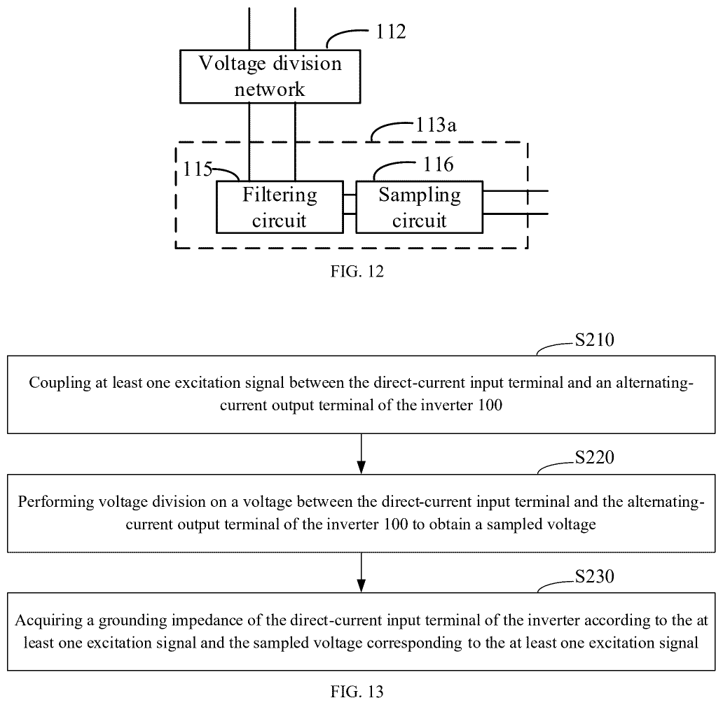

In some embodiments, referring to FIG. 12, the first sampling unit 113a may include a filtering circuit 115 and a sampling circuit 116, and the filtering circuit 115 may be connected to the voltage division network 112 and the sampling circuit 116, respectively, and configured to filter a voltage component in the sampled voltage other than a voltage component with a frequency of the excitation signal.

In some embodiments, the first sampling unit 113a may include an ADC (analog to digital converter) sampling unit. The controller 114 may receive a sampling voltage in a digital form. Correspondingly, the controller 114 may include a filtering unit configured to filter a voltage component in the sampled voltage other than a voltage component with the frequency of the excitation signal.

Furthermore, referring to FIG. 13, a grounding impedance measurement method is provided in the present disclosure, which is configured to measure a grounding impedance of a direct-current input terminal of an inverter 100. The method includes step 210 to step 230.

Step 210 includes coupling at least one excitation signal between the direct-current input terminal and an alternating-current output terminal of the inverter 100.

Step 220 includes performing voltage division on a voltage between the direct-current input terminal and the alternating-current output terminal of the inverter 100 to obtain a sampled voltage.

Step 230 includes acquiring a grounding impedance of the direct-current input terminal of the inverter according to the at least one excitation signal and the sampled voltage corresponding to the at least one excitation signal.

In some embodiments, the method may further include: coupling a first excitation signal and a second excitation signal between the direct-current input terminal and the alternating-current output terminal of the inverter 100, respectively; and acquiring a first sampled voltage corresponding to the first excitation signal and a second sampled voltage corresponding to the second excitation signal, respectively, and acquiring the grounding impedance of the direct-current input terminal of the inverter 100 according to a difference between the first excitation signal and the second excitation signal and a difference between the first sampled voltage and the second sampled voltage.

In some embodiments, the method may further include: coupling at least two different excitation signals between the direct-current input terminal and the alternating-current output terminal of the inverter 100, respectively; and acquiring direct-current input voltages of the direct-current input terminal of the inverter 100 and sampled voltages corresponding to the at least two different excitation signals, and acquiring the grounding impedance of the direct-current input terminal of the inverter 100 according to the at least two different excitation signals and the direct-current input voltages and the sampled voltages corresponding to the at least two different excitation signals.

In some embodiments, the method may further include comparing the grounding impedance with a preset threshold to determine whether the grounding impedance is abnormal.

An inverter 100 is provided in the present disclosure, including the above grounding impedance measurement apparatus 100 and the DC/AC converter 120.

In the present disclosure, the signal source V_{c} and the coupling impedance network 111 are disposed between the direct-current input terminal and the alternating-current output terminal of the inverter 100, to construct a high-resistance circuit. The excitation signal is introduced into the high-resistance circuit, and the grounding impedance of the direct-current input terminal of the inverter 100 is acquired according to the excitation signal and the sampling voltage corresponding to the excitation signal. In a case that the inverter 100 has no grounding line, the grounding impedance of the direct-current input terminal of the inverter 100 may be measured.

The grounding impedance measurement apparatus 110, the grounding impedance measurement method, and the inverter 100 in the present disclosure may be corresponding to each other. Technical features and beneficial effects described in the above embodiments of the ground impedance measurement apparatus 110 may be applicable to the embodiments of both the ground impedance measurement method and the inverter 100.

The various technical features of the above embodiments may be combined arbitrarily, and all possible combinations of the various technical features of the above-described embodiments have not been described for the sake of conciseness of description. However, as long as there is no contradiction in the combinations of these technical features, they should be considered to be within the scope of the present description.

The above-described embodiments express only several embodiments of the present disclosure, which are described in a more specific and detailed manner, but are not to be construed as a limitation on the scope of the present disclosure. For the skill in the art, several deformations and improvements can be made without departing from the conception of the present disclosure, all of which fall within the scope of protection of the present disclosure. Therefore, the scope of protection of the present disclosure shall be subject to the attached claims.

What is claimed is:

1. A grounding impedance measurement apparatus, comprising a signal source, a coupling impedance network, a voltage division network, a sampling module, and a controller, wherein
the signal source is configured to provide an excitation signal;
the coupling impedance network is connected to the signal source, and configured to couple the excitation signal between a direct-current input terminal and an alternating-current output terminal of an inverter, wherein the alternating-current output terminal of the inverter is connected to a power grid;
the voltage division network is configured to perform voltage division on a voltage between the direct-current input terminal and the alternating-current output terminal to provide a divided voltage;
the sampling module is connected to the voltage division network, and configured to sample the divided voltage and acquire a sampled voltage;
the controller is connected to the signal source and the sampling module, respectively, and configured to control the signal source to provide at least one excitation signal and acquire a grounding impedance of the direct-current input terminal of the inverter according to the at least one excitation signal and the sampled voltage corresponding to the at least one excitation signal.

2. The grounding impedance measurement apparatus of claim 1, wherein the controller is further configured to control the signal source to provide a first excitation signal and a second excitation signal, respectively, the sampling module is further configured to acquire a first sampled voltage corresponding to the first excitation signal and a second sampled voltage corresponding to the second excitation signal, and the controller is further configured to acquire the grounding impedance of the direct-current input terminal of the inverter according to a difference between the first excitation signal and the second excitation signal and a difference between the first sampled voltage and the second sampled voltage.

3. The grounding impedance measurement apparatus of claim 1, wherein an output terminal of the signal source is connected to a port of the direct-current input terminal and the other output terminal of the signal source is connected to a port of the alternating-current output terminal via the coupling impedance network.

4. The grounding impedance measurement apparatus of claim 3, wherein the signal source comprises a direct-current voltage conversion circuit or a rectifier circuit.

5. The grounding impedance measurement apparatus of claim 3, wherein the signal source comprises a switch circuit, which comprises at least one switch, and different excitation signals are output by controlling an on-state of the at least one switch.

6. The grounding impedance measurement apparatus of claim 3, wherein the inverter comprises a full-bridge circuit or a half-bridge circuit, which is connected to the direct-current input terminal, the signal source is a part of the full-bridge circuit or a part of the half-bridge circuit, and the excitation signal comprises a direct-current input voltage of the direct-current input terminal or 0.

7. The grounding impedance measurement apparatus of claim 1, wherein the voltage division network is connected between a port of the direct-current input terminal of the inverter and a port of the alternating-current output terminal of the inverter.

8. The grounding impedance measurement apparatus of claim 1, wherein the voltage division network is connected to the coupling impedance network in series.

9. The grounding impedance measurement apparatus of claim 1, wherein the sampling module comprises a first sampling unit, which is connected to the voltage division network and configured to acquire the sampled voltage.

10. The grounding impedance measurement apparatus of claim 9, wherein the first sampling unit comprises a filtering circuit and a sampling circuit, and the filtering circuit is connected to the voltage division network and the sampling circuit, respectively, and configured to filter a voltage component in the sampled voltage other than a voltage component with a frequency of the excitation signal.

11. The grounding impedance measurement apparatus of claim 9, wherein the controller comprises a filtering unit configured to filter a voltage component in the sampled voltage other than a voltage component with a frequency of the excitation signal.

12. The grounding impedance measurement apparatus of claim 9, wherein the sampling module further comprises a second sampling unit connected to the direct-current input terminal of the inverter and configured to acquire a direct-current input voltage and provide the direct-current input voltage to the controller, and the controller is configured to control the signal source to provide at least two different excitation signals, and acquire the grounding impedance of the direct-current input terminal of the inverter according to the at least two different excitation signals and sampled voltages and direct-current input voltages corresponding to the at least two different excitation signals.

13. The grounding impedance measurement apparatus of claim 1, wherein the excitation signal comprises a direct-current signal, an alternating-current signal, or a superposed signal of a direct-current signal and an alternating-current signal.

14. The grounding impedance measurement apparatus of claim 1, wherein the controller is configured to compare the grounding impedance with a preset threshold to determine whether the grounding impedance is abnormal.

15. A grounding impedance measurement method, configured to measure a grounding impedance of a direct-current input terminal of an inverter, wherein the method comprises:
coupling at least one excitation signal between the direct-current input terminal and an alternating-current output terminal of the inverter;
performing voltage division on a voltage between the direct-current input terminal and the alternating-current output terminal of the inverter to obtain a sampled voltage; and
acquiring a grounding impedance of the direct-current input terminal of the inverter according to the at least one excitation signal and the sampled voltage corresponding to the at least one excitation signal.

16. The method of claim 15, further comprising:
coupling a first excitation signal and a second excitation signal between the direct-current input terminal and the alternating-current output terminal of the inverter, respectively; and
acquiring a first sampled voltage corresponding to the first excitation signal and a second sampled voltage corresponding to the second excitation signal, respectively, and acquiring the grounding impedance of the direct-current input terminal of the inverter according to a difference between the first excitation signal and the second excitation signal and a difference between the first sampled voltage and the second sampled voltage.

17. The method of claim 15, further comprising:
coupling at least two different excitation signals between the direct-current input terminal and the alternating-current output terminal of the inverter, respectively; and
acquiring direct-current input voltages of the direct-current input terminal of the inverter and sampled voltages corresponding to the at least two different excitation signals, and acquiring the grounding impedance of the direct-current input terminal of the inverter according to the at least two different excitation signals and the direct-current input voltages and the sampled voltages corresponding to the at least two different excitation signals.

18. The method of claim 17, further comprising:
comparing the grounding impedance with a preset threshold to determine whether the grounding impedance is abnormal.

19. An inverter, comprising the grounding impedance measurement apparatus of claim 1 and a DC/AC converter, wherein the DC/AC converter is connected between the direct-current input terminal and the alternating-current output terminal of the inverter and configured to convert a direct current to an alternating current.

20. The inverter of claim 19, wherein the controller is further configured to control the signal source to provide a first excitation signal and a second excitation signal, respectively, the sampling module is further configured to acquire a first sampled voltage corresponding to the first excitation signal and a second sampled voltage corresponding to the second excitation signal, and the controller is further configured to acquire the grounding impedance of the direct-current input terminal of the inverter according to a difference between the first excitation signal and the second excitation signal and a difference between the first sampled voltage and the second sampled voltage.
